(19) United States
(12) Patent Application Publication
(10) Pub. No.: US 2026/0098903 A1
(43) Pub. Date: Apr. 9, 2026

(54) BATTERY STATE OF CHARGE ESTIMATION USING VIRTUAL CELL MODELING

(71) Applicant: GM Global Technology Operations LLC, Detroit, MI (US)

(72) Inventors: Cheng Peng, Shanghai (CN); Chengwu Duan, Shanghai (CN); Jun-Mo Kang, Ann Arbor, MI (US)

(21) Appl. No.: 18/921,537

(22) Filed: Oct. 21, 2024

(30) Foreign Application Priority Data
Oct. 9, 2024 (CN) 202411404846.1

(51) Int. Cl. G01R 31/367; G01R 31/00; G01R 31/382; G01R 31/389

(52) U.S. Cl. CPC G01R 31/367; G01R 31/007; G01R 31/382; G01R 31/389

(57) ABSTRACT

A method for determining a state of charge (SOC) of a battery may include determining a measured physical battery current flowing through the battery. The method further may include determining an estimated physical battery current using a physical battery cell model. The physical battery cell model is an equivalent circuit model of a first battery cell. The method further may include determining an estimated SOC of the battery based at least in part on the measured physical battery current and the estimated physical battery current using a virtual battery cell model. The virtual battery cell model is an equivalent circuit model of a second battery cell. The second battery cell is a computer-simulated electrochemical battery cell modeled in series with the physical battery cell model. The method further may include determining the SOC of the battery based at least in part on the estimated SOC of the battery.

### CROSS-REFERENCE TO RELATED APPLICATIONS

The present application claims priority to Chinese patent application number 202411404846.1, filed Oct. 9, 2024, the contents of which are incorporated by reference.

### INTRODUCTION

The present disclosure relates to systems and methods for state of charge estimation for batteries.

Rechargeable batteries, such as, for example, lithium-ion batteries, are used in a variety of applications, from electric vehicles to residential batteries and grid-scale applications. An important aspect of the effective and efficient operation of rechargeable battery systems is accurate and reliable determination of battery state of charge (SOC) under various operating conditions. For example, determining the state of charge (SOC) of batteries in electric/hybrid-electric vehicles is important for power management and occupant comfort and convenience. State of charge (SOC) is not a directly measurable characteristic of a battery and must be estimated based on directly measurable characteristics such as battery voltage and current flow. However, with some battery chemistries, the relationship between SOC and directly measurable battery characteristics may be highly non-linear, presenting challenges for accurate and repeatable SOC estimation without accumulating error over time.

Thus, while battery SOC estimation systems and methods achieve their intended purpose, there is a need for a new and improved system and method for determining battery cell state of charge (SOC) for battery chemistries having non-linear relationships between SOC and directly measurable battery characteristics.

### SUMMARY

According to several aspects, a method for determining a state of charge (SOC) of a battery is provided. The method may include determining a measured physical battery current flowing through the battery. The method further may include determining an estimated physical battery current using a physical battery cell model. The physical battery cell model is an equivalent circuit model of a first battery cell. The method further may include determining an estimated SOC of the battery based at least in part on the measured physical battery current and the estimated physical battery current using a virtual battery cell model. The virtual battery cell model is an equivalent circuit model of a second battery cell. The second battery cell is a computer-simulated electrochemical battery cell modeled in series with the physical battery cell model. The method further may include determining the SOC of the battery based at least in part on the estimated SOC of the battery.

In another aspect of the present disclosure, determining the estimated physical battery current further may include computing the estimated physical battery current based at least in part on one or more battery parameters of the physical battery cell model. The first battery cell is a lithium-iron phosphate (LiFePO4) battery cell.

In another aspect of the present disclosure, determining the estimated SOC of the battery further may include calculating an innovation factor based at least in part on the measured physical battery current, the estimated physical battery current, and one or more battery parameters of the physical battery cell model. Determining the estimated SOC of the battery further may include determining the estimated SOC of the battery based at least in part on the innovation factor.

In another aspect of the present disclosure, determining the estimated SOC of the battery further may include determining an estimated SOC of the second battery cell using Kalman filtering based at least in part on the innovation factor. Determining the estimated SOC of the battery further may include determining the estimated SOC of the battery based at least in part on the estimated SOC of the second battery cell.

In another aspect of the present disclosure, calculating the innovation factor further may include determining the one or more battery parameters. The one or more battery parameters includes a virtual RC pair resistance of the virtual battery cell model. Calculating the innovation factor further may include calculating the innovation factor using a formula:

$$e = \frac{{R}_{1 , VC}}{{R}_{1 , VC} * {C}_{1 , VC} * s + 1} * ( \overline{I} - )$$

where e is the innovation factor, R_{1,VC} is the virtual RC pair resistance, Ī is the measured physical battery current, [symbol] is the estimated physical battery current, C_{1,VC} is a virtual RC pair capacitance, and s is the Laplace variable.

In another aspect of the present disclosure, determining the one or more battery parameters further may include determining a difference between a simulated virtual battery cell terminal voltage and an estimated virtual battery cell terminal voltage. The simulated virtual battery cell terminal voltage is determined using the virtual battery cell model based on the measured physical battery current. The estimated virtual battery cell terminal voltage is determined using the virtual battery cell model based on the estimated physical battery current. Determining the one or more battery parameters further may include setting the virtual RC pair resistance to be equal to a first resistance value in response to determining that the difference between a simulated virtual battery cell terminal voltage and an estimated virtual battery cell terminal voltage is greater than or equal to a predetermined convergence threshold. Determining the one or more battery parameters further may include setting the virtual RC pair resistance to be equal to a second resistance value in response to determining that the difference between a simulated virtual battery cell terminal voltage and an estimated virtual battery cell terminal voltage is less than the predetermined convergence threshold. The second resistance value is less than the first resistance value.

In another aspect of the present disclosure, calculating the innovation factor further may include determining the one or more battery parameters. The one or more battery parameters includes a virtual RC pair resistance of the virtual battery cell model. Calculating the innovation factor further may include determining the one or more battery parameters. The one or more battery parameters further includes a parameter deviation factor of the physical battery cell model. Calculating the innovation factor further may include determining the one or more battery parameters. The one or more battery parameters further includes a hysteresis deviation constant of the physical battery cell model. Calculating the innovation factor further may include determining a mean difference between a charging open circuit voltage of the first battery cell and a discharging open circuit voltage of the first battery cell within a predetermined SOC range. Calculating the innovation factor further may include calculating the innovation factor using a formula:

$$e = \frac{{R}_{1 , VC}}{{R}_{1 , VC} * {C}_{1 , VC} * s + 1} * [ ( \overline{I} - ) - \frac{α - 1}{α} * \overline{I} + \frac{0.5 * {G}_{m} - d}{α * {R}_{0 , PC}} ]$$

where e is the innovation factor, R_{1,VC} is the virtual RC pair resistance, C_{1,VC} is a virtual RC pair capacitance, s is the Laplace variable, Ī is the measured physical battery current, [symbol] is the estimated physical battery current, a is the parameter deviation factor, Gₘ is the mean difference between the charging open circuit voltage of the first battery cell and the discharging open circuit voltage of the first battery cell within the predetermined SOC range, d is the hysteresis deviation constant, and R_{0,PC} is a series resistance of the physical battery cell model.

In another aspect of the present disclosure, determining the parameter deviation factor may include determining the parameter deviation factor using a formula:

$$α = \frac{1}{1 - \frac{( \overline{I} - )}{I}}$$

where α is the parameter deviation factor, Ī is the measured physical battery current, and [symbol] is the estimated physical battery current.

In another aspect of the present disclosure, determining the hysteresis deviation constant further may include determining the hysteresis deviation constant using a formula:

$$d = \frac{\vert p \cdot {Q}_{c} \vert}{\vert p \cdot {Q}_{c} \vert + \vert q \cdot {Q}_{d} \vert} {G}_{m}$$

where d is the hysteresis deviation constant, p is a first calibratable constant, q is a second calibratable constant, Q_{c} is a charge capacity of the first battery cell, Q_{d} is a discharge capacity of the first battery cell, and Gₘ is the mean difference between the charging open circuit voltage of the first battery cell and the discharging open circuit voltage of the first battery cell within the predetermined SOC range.

In another aspect of the present disclosure, determining the SOC of the battery further may include comparing an estimated SOC of the battery to a predetermined SOC range. Determining the SOC of the battery further may include determining the SOC of the battery to be equal to the estimated SOC of the battery in response to determining that the estimated SOC of the battery is within the predetermined SOC range. Determining the SOC of the battery further may include determining the SOC of the battery using coulomb counting in response to determining that the estimated SOC of the battery is outside of the predetermined SOC range.

According to several aspects, a system for determining a state of charge (SOC) of a battery for a vehicle is provided. The system may include the battery including a first battery cell, one or more battery sensors in electrical communication with the battery, and a controller in electrical communication with the one or more battery sensors. The controller is programmed to determine a measured physical battery current flowing through the battery using the one or more battery sensors. The controller is further programmed to determine an estimated physical battery current using a physical battery cell model. The physical battery cell model is an equivalent circuit model of the first battery cell. The controller is further programmed to determine the SOC of the battery based at least in part on the measured physical battery current and the estimated physical battery current using a virtual battery cell model. The virtual battery cell model is an equivalent circuit model of a second battery cell. The second battery cell is a computer-simulated electrochemical battery cell modeled in series with the physical battery cell model.

In another aspect of the present disclosure, to determine the SOC of the battery, the controller is further programmed to calculate an innovation factor based at least in part on the measured physical battery current, the estimated physical battery current, and one or more battery parameters of the physical battery cell model. To determine the SOC of the battery, the controller is further programmed to determine an estimated SOC of the second battery cell using Kalman filtering based at least in part on the innovation factor. To determine the SOC of the battery, the controller is further programmed to determine the SOC of the battery based at least in part on the estimated SOC of the second battery cell.

In another aspect of the present disclosure, to calculate the innovation factor, the controller is further programmed to determine the one or more battery parameters. The one or more battery parameters includes a virtual RC pair resistance of the virtual battery cell model. To calculate the innovation factor, the controller is further programmed to calculate the innovation factor using a formula:

$$e = \frac{{R}_{1 , VC}}{{R}_{1 , VC} * {C}_{1 , VC} * s + 1} * ( \overline{I} - )$$

where e is the innovation factor, R_{1,VC} is the virtual RC pair resistance, Ī is the measured physical battery current, [symbol] is the estimated physical battery current, C_{1,VC} is a virtual RC pair capacitance, and s is the Laplace variable.

In another aspect of the present disclosure, to determine the one or more battery parameters, the controller is further programmed to determine a difference between a simulated virtual battery cell terminal voltage and an estimated virtual battery cell terminal voltage. The simulated virtual battery cell terminal voltage is determined using the virtual battery cell model based on the measured physical battery current. The estimated virtual battery cell terminal voltage is determined using the virtual battery cell model based on the estimated physical battery current. To determine the one or more battery parameters, the controller is further programmed to set the virtual RC pair resistance to be equal to a first resistance value in response to determining that the difference between a simulated virtual battery cell terminal voltage and an estimated virtual battery cell terminal voltage is greater than or equal to a predetermined convergence threshold. To determine the one or more battery parameters, the controller is further programmed to set the virtual RC pair resistance to be equal to a second resistance value in response to determining that the difference between a simulated virtual battery cell terminal voltage and an estimated virtual battery cell terminal voltage is less than the predetermined convergence threshold. The second resistance value is less than the first resistance value.

In another aspect of the present disclosure, to calculate the innovation factor, the controller is further programmed to determine the one or more battery parameters. The one or more battery parameters includes a virtual RC pair resistance of the virtual battery cell model. To calculate the innovation factor, the controller is further programmed to determine the one or more battery parameters. The one or more battery parameters further includes a parameter deviation factor of the physical battery cell model. To calculate the innovation factor, the controller is further programmed to determine the one or more battery parameters. The one or more battery parameters further includes a hysteresis deviation constant of the physical battery cell model. To calculate the innovation factor, the controller is further programmed to determine a mean difference between a charging open circuit voltage of the first battery cell and a discharging open circuit voltage of the first battery cell within a predetermined SOC range. To calculate the innovation factor, the controller is further programmed to calculate the innovation factor using a formula:

$$e = \frac{{R}_{1 , VC}}{{R}_{1 , VC} * {C}_{1 , VC} * s + 1} * [ ( \overline{I} - ) - \frac{α - 1}{α} * \overline{I} + \frac{0.5 * {G}_{m} - d}{α * {R}_{0 , PC}} ]$$

where e is the innovation factor, R_{1,VC} is the virtual RC pair resistance, C_{1,VC} is a virtual RC pair capacitance, s is the Laplace variable, Ī is the measured physical battery current, [symbol] is the estimated physical battery current, a is the parameter deviation factor, Gₘ is the mean difference between the charging open circuit voltage of the first battery cell and the discharging open circuit voltage of the first battery cell within the predetermined SOC range, d is the hysteresis deviation constant, and R_{0,PC} is a series resistance of the physical battery cell model.

In another aspect of the present disclosure, to determine the parameter deviation factor, the controller is further programmed to determine the parameter deviation factor using a formula:

$$α = \frac{1}{1 - \frac{( \overline{I} - )}{I}}$$

where α is the parameter deviation factor, Ī is the measured physical battery current, and [symbol] is the estimated physical battery current.

In another aspect of the present disclosure, to determine the hysteresis deviation constant, the controller is further programmed to determine the hysteresis deviation constant using a formula:

$$d = \frac{\vert p \cdot {Q}_{c} \vert}{\vert p \cdot {Q}_{c} \vert + \vert q \cdot {Q}_{d} \vert} {G}_{m}$$

where d is the hysteresis deviation constant, p is a first calibratable constant, q is a second calibratable constant, Q_{c} is a charge capacity of the first battery cell, Q_{d} is a discharge capacity of the first battery cell, and Gₘ is the mean difference between the charging open circuit voltage of the first battery cell and the discharging open circuit voltage of the first battery cell within the predetermined SOC range.

According to several aspects, a method for determining a state of charge (SOC) of a battery is provided. The method may include determining a measured physical battery current flowing through the battery. The method further may include determining an estimated physical battery current using a physical battery cell model. The physical battery cell model is an equivalent circuit model of a first battery cell. The first battery cell is a lithium-iron phosphate (LiFePO4) battery cell. The method further may include determining the SOC of the battery based at least in part on the measured physical battery current and the estimated physical battery current using a virtual battery cell model. The virtual battery cell model is an equivalent circuit model of a second battery cell. The second battery cell is a computer-simulated electrochemical battery cell modeled in series with the physical battery cell model. The second battery cell is a nickel cobalt manganese (NCM) battery cell.

In another aspect of the present disclosure, determining the SOC of the battery further may include calculating an innovation factor based at least in part on the measured physical battery current, the estimated physical battery current, and one or more battery parameters of the physical battery cell model. Determining the SOC of the battery further may include determining an estimated SOC of the second battery cell using Kalman filtering based at least in part on the innovation factor. Determining the SOC of the battery further may include determining the SOC of the battery based at least in part on the estimated SOC of the second battery cell.

In another aspect of the present disclosure, calculating the innovation factor further may include determining a difference between a simulated virtual battery cell terminal voltage and an estimated virtual battery cell terminal voltage. The simulated virtual battery cell terminal voltage is determined using the virtual battery cell model based on the measured physical battery current. The estimated virtual battery cell terminal voltage is determined using the virtual battery cell model based on the estimated physical battery current. Calculating the innovation factor further may include setting a virtual RC pair resistance to be equal to a first resistance value in response to determining that the difference between a simulated virtual battery cell terminal voltage and an estimated virtual battery cell terminal voltage is greater than or equal to a predetermined convergence threshold. Calculating the innovation factor further may include setting the virtual RC pair resistance to be equal to a second resistance value in response to determining that the difference between a simulated virtual battery cell terminal voltage and an estimated virtual battery cell terminal voltage is less than the predetermined convergence threshold. The second resistance value is less than the first resistance value. Calculating the innovation factor further may include calculating the innovation factor using a formula:

$$e = \frac{{R}_{1 , VC}}{{R}_{1 , VC} * {C}_{1 , VC} * s + 1} * ( \overline{I} - )$$

where e is the innovation factor, R_{1,VC} is the virtual RC pair resistance, Ī is the measured physical battery current, [symbol] is the estimated physical battery current, C_{1,VC} is a virtual RC pair capacitance, and s is the Laplace variable.

Further areas of applicability will become apparent from the description provided herein. It should be understood that the description and specific examples are intended for purposes of illustration only and are not intended to limit the scope of the present disclosure.

### BRIEF DESCRIPTION OF THE DRAWINGS

The drawings described herein are for illustration purposes only and are not intended to limit the scope of the present disclosure in any way.

FIG. 1 is a schematic diagram of a system for determining a state of charge (SOC) of a battery, according to an exemplary embodiment;

FIG. 2 is a block diagram of a software algorithm for determining a state of charge (SOC) of a battery, according to an exemplary embodiment; and

FIG. 3 is a flowchart of a method for determining a state of charge (SOC) of a battery, according to an exemplary embodiment.

### DETAILED DESCRIPTION

The following description is merely exemplary in nature and is not intended to limit the present disclosure, application, or uses.

In aspects of the present disclosure, determining the state of charge (SOC) of batteries in electric/hybrid-electric vehicles is important for power management and occupant comfort and convenience. However, some battery chemistries, such as, for example, lithium-iron phosphate (LiFePO4) present challenges for SOC estimation because of their relatively flat OCV-SOC curve through large SOC ranges. Therefore, the present disclosure provides a new and improved system and method for determining battery SOC using computer simulation of a virtual battery cell with adjustable parameters for increased convergence speed.

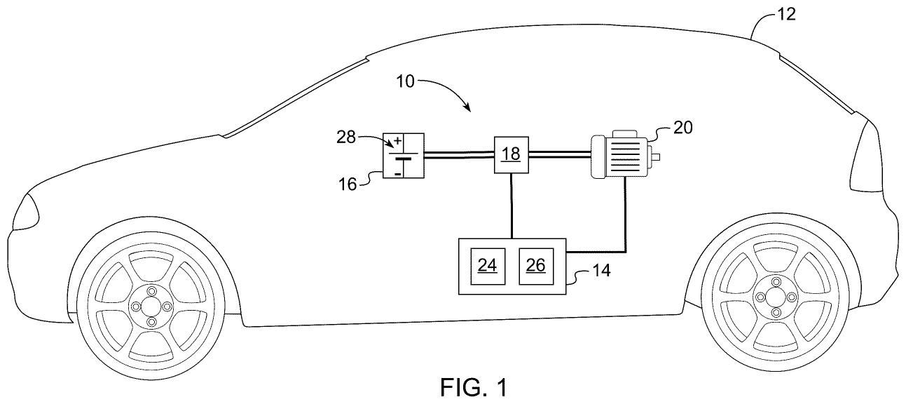

Referring to FIG. 1, a system for determining a state of charge (SOC) of a battery is illustrated and generally indicated by reference number 10. The system 10 is shown with an exemplary vehicle 12. While a passenger vehicle is illustrated, it should be appreciated that the vehicle 12 may be any type of vehicle without departing from the scope of the present disclosure. The system 10 generally includes a controller 14, a battery 16, a battery management system 18, and an electrical load 20.

The controller 14 is used to implement a method 100 for determining a state of charge (SOC) of a battery using a software algorithm 22, as will be described below. The controller 14 includes at least one processor 24 and a non-transitory computer readable storage device or media 26. The processor 24 may be a custom made or commercially available processor, a central processing unit (CPU), a graphics processing unit (GPU), an auxiliary processor among several processors associated with the controller 14, a semiconductor-based microprocessor (in the form of a microchip or chip set), a macroprocessor, a combination thereof, or generally a device for executing instructions.

The computer readable storage device or media 26 may include volatile and nonvolatile storage in read-only memory (ROM), random-access memory (RAM), and keep-alive memory (KAM), for example. KAM is a persistent or non-volatile memory that may be used to store various operating variables while the processor 24 is powered down. The computer-readable storage device or media 26 may be implemented using a number of memory devices such as PROMs (programmable read-only memory), EPROMs (electrically PROM), EEPROMs (electrically erasable PROM), flash memory, or another electric, magnetic, optical, or combination memory devices capable of storing data, some of which represent executable instructions, used by the controller 14 to control various systems of the vehicle 12.

The controller 14 may also consist of multiple controllers which are in electrical communication with each other. The controller 14 may be inter-connected with additional systems and/or controllers of the vehicle 12, allowing the controller 14 to access data such as, for example, speed, acceleration, braking, and steering angle of the vehicle 12.

The controller 14 is in electrical communication with the battery management system 18 and the electrical load 20. In an exemplary embodiment, the electrical communication is established using, for example, a CAN network, a FLEXRAY network, a local area network (e.g., WiFi, ethernet, and the like), a serial peripheral interface (SPI) network, or the like. It should be understood that various additional wired and wireless techniques and communication protocols for communicating with the controller 14 are within the scope of the present disclosure. It should further be understood that, in the scope of the present disclosure, electrical communication also includes power and/or energy transfer between electrical devices (e.g., using conducting wires and/or wireless power transmission techniques).

The battery 16 stores and provides electrical energy in the form of direct current (DC) for operation of the vehicle 12. In an exemplary embodiment, the battery 16 includes one or more battery cells (e.g., lithium-ion battery cells) electrically connected in series and/or parallel to provide an increased voltage and/or current-carrying capacity. In the present disclosure, the battery 16 is discussed in terms of a single lithium-iron phosphate (LiFePO4) battery cell, referred to as a first battery cell 28. It should be understood that the present disclosure is applicable to any number of battery cells in any series/parallel configuration and having any battery chemistry. In a non-limiting example, the plurality of battery cells are housed in an enclosure configured to protect the plurality of battery cells from mechanical vibration, water intrusion, and dust intrusion. The enclosure is also configured to provide temperature regulation (e.g., using a liquid cooling system, a resistive heating system, and/or the like). In an exemplary embodiment, the battery 16 provides a DC voltage across a positive and negative output terminal. The positive and negative output terminals are electrically connected to the battery management system 18, as will be discussed in greater detail below.

The battery management system 18 is used to monitor the battery 16, provide information about a state of the battery 16 to other systems (e.g., the controller 14), and optimize use of the battery 16 to prolong a usable life of the battery 16 and protect the battery 16 from damage. In an exemplary embodiment, the battery management system 18 facilitates an electrical connection between the battery 16 and the electrical load 20. In a non-limiting example, the battery management system 18 includes one or more electrical and/or electromechanical switches (e.g., contactors) and may disconnect the battery 16 from the electrical load 20 for protection of the battery 16.

In an exemplary embodiment, the battery management system 18 performs measurements of various characteristics of the battery 16, including, for example, a terminal voltage of the battery, an electrical current flow through the battery, a temperature of the battery, and/or the like. In a non-limiting example, the battery management system 18 includes one or more battery sensors in electrical communication with the battery. For example, the one or more battery sensors include a current sensor (e.g., a shunt resistor current sensor, an inductive current sensor, and/or the like), a voltage sensor (e.g., an analog-to-digital converter), a temperature sensor (e.g., a thermistor), and/or the like. The battery management system 18 is in electrical communication with the battery 16 and the electrical load 20 to transfer power between the battery 16 and the electrical load 20. The battery management system 18 is in electrical communication with the controller 14 to provide battery status information to the controller 14 and/or to receive battery control signals from the controller 14.

The electrical load 20 is an electrical and/or electromechanical device which consumes energy from the battery 16 to operate the vehicle 12. In a non-limiting example, the electrical load 20 is a traction motor used to convert electrical energy from the battery 16 to mechanical energy (i.e., rotational energy) to propel the vehicle 12. In an exemplary embodiment, the traction motor is a three-phase alternating current (AC) induction motor capable of converting AC energy to mechanical energy. In a non-limiting example, the traction motor includes a stator having a plurality of stator windings and a rotor disposed rotatably within the stator having a plurality of rotor windings. The stator windings are excited by three-phase AC produced by an inverter to produce a rotating stator magnetic field.

The rotating stator magnetic field induces currents in the rotor windings, which in turn produces a rotor magnetic field which interacts with the rotating stator magnetic field causing the rotor to rotate. The amplitude, frequency, and/or relative phase shift of the excitation of each of the three phases of the stator windings controls speed, direction, and/or torque of the traction motor. It should be understood that the electrical load 20 may include additional devices, such as, for example, vehicle lighting, climate control systems, and/or the like without departing from the scope of the present disclosure. The electrical load 20 is in electrical communication with the controller 14 for monitoring and/or control of the electrical load 20.

In the scope of the present disclosure, the term “measured” refers to values directly or indirectly measured from a real-world system. Measured values are denoted with bar notation (e.g., x). In the scope of the present disclosure, the term “simulated” refers to values derived using mathematical and/or computer-simulated models on the basis of “measured” values. Simulated values are denoted with tilde notation (e.g., \tilde{x}). The term “estimated” refers to values derived using mathematical and/or computer-simulated models on the basis of “simulated” values. Estimated values are denoted with hat notation (e.g., \hat{x}).

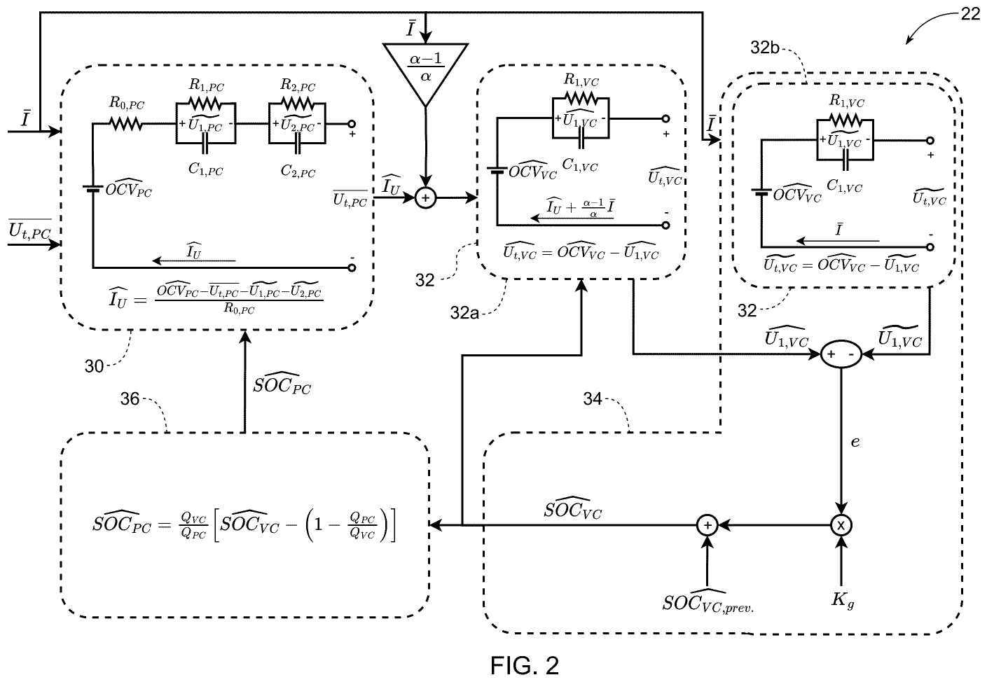

Referring to FIG. 2, a block diagram of the software algorithm 22 is shown. The software algorithm 22 includes a physical battery cell model 30, two instances of a virtual battery cell model 32 (including a first virtual battery cell model instance 32a and a second virtual battery cell model instance 32b), a Kalman filtering module 34, and a state of charge (SOC) conversion module 36.

The physical battery cell model 30 is an equivalent circuit model (ECM) of the first battery cell 28 of the battery 16 (e.g., the LiFePO4 cell of the battery 16). In an exemplary embodiment, the ECM of the first battery cell 28 includes a series resistance (R_{0,PC}) and one or more parallel resistor-capacitor (RC) pairs (e.g., R_{1,PC}, R_{2,PC}, C_{1,PC}, and C_{2,PC}). The series resistance and the resistance and capacitance of the one or more RC pairs are referred to as one or more battery parameters of the physical battery cell model 30. A relationship between an estimated physical battery current ( [symbol] ) flowing through the first battery cell 28, an estimated open circuit voltage of the first battery cell 28 ( [symbol] ), and a measured terminal voltage of the first battery cell 28 (U̅_̅{̅t̅,̅P̅C̅}̅) is modeled as:

$$= \frac{- \overline{{U}_{t , PC}} - -}{{R}_{0 , PC}} \qquad ( 1 )$$

where [symbol] is the estimated physical battery current flowing through the first battery cell 28, [symbol] _{PC} is the estimated open circuit voltage of the first battery cell 28 (e.g., determined based on a known OCV-SOC relationship of the first battery cell 28), U̅_̅{̅t̅,̅P̅C̅}̅ is the terminal voltage of the first battery cell 28, [symbol] is a voltage across a first RC pair of the physical battery cell model 30, [symbol] is a voltage across a second RC pair of the physical battery cell model 30, and R_{0,PC} is a series resistance of the first battery cell 28. Accordingly, the physical battery cell model 30 is used to calculate the estimated physical battery current ( [symbol] ) based on the aforementioned inputs.

The virtual battery cell model 32 is an equivalent circuit model (ECM) of a second battery cell. The second battery cell is a computer-simulated electrochemical battery cell. In a non-limiting example, the second battery cell has a chemistry with a relatively stronger correlation (i.e., a higher correlation coefficient) and/or more linear correlation between open circuit voltage and state of charge. In a non-limiting example, the second battery cell is a nickel cobalt manganese (NCM) battery cell. It should be understood that the second battery cell is not a physical battery cell within the battery 16, but rather a computer simulation of a battery cell using the virtual battery cell model 32. Therefore, while the battery 16 only physically contains the first battery cell 28, the controller 14 uses the software algorithm 22 to model the battery 16 as a series connection of the physical battery cell model 30 and the virtual battery cell model 32.

In an exemplary embodiment, the ECM of the second battery cell includes one or more parallel virtual resistor-capacitor (RC) pairs (e.g., R_{1,VC} and C_{1,VC}). The resistance and capacitance of the one or more virtual RC pairs are referred to as one or more battery parameters of the virtual battery cell model 32. In the first virtual battery cell model instance 32a, the ECM of the second battery cell is used to model a relationship between an estimated open circuit voltage of the second battery cell ( [symbol] ) and an estimated terminal voltage of the second battery cell ( [symbol] ):

$$= - \qquad ( 2 )$$

where [symbol] is the estimated terminal voltage of the second battery cell, [symbol] is the estimated open circuit voltage of the second battery cell (e.g., determined based on a known OCV-SOC relationship of the second battery cell), and [symbol] is an estimated voltage across a first RC pair of the first virtual battery cell model instance 32a assuming a current flow of

$$+ \frac{α - 1}{α} \overline{I} .$$

In the second virtual battery cell model instance 32b, the ECM of the second battery cell is used to model a relationship between the estimated open circuit voltage of the second battery cell ( [symbol] ) and a simulated terminal voltage of the second battery cell ( [symbol] ):

$$= - \qquad ( 3 )$$

where [symbol] is the simulated terminal voltage of the second battery cell, [symbol] is the estimated open circuit voltage of the second battery cell (e.g., determined based on a known OCV-SOC relationship of the second battery cell), and [symbol] is a simulated voltage across a first RC pair of the first virtual battery cell model instance 32a assuming a current flow of Ī.

The Kalman filtering module 34 uses Kalman filtering to determine an estimated state of charge (SOC) of the second battery cell ( [symbol] ), as will be discussed in greater detail below. As discussed above, the second battery cell is not a physical battery cell, but rather a computer-simulated battery cell. Therefore, the estimated SOC of the second battery cell is a computer-simulated SOC based on the virtual battery cell model 32.

The state of charge (SOC) conversion module 36 determines an estimated SOC of the first battery cell 28 ( [symbol] ) based on the estimated SOC of the second battery cell ( [symbol] ) determined using the Kalman filtering module 34. In an exemplary embodiment, the SOC conversion module 36 uses a conversion equation:

$$= \frac{{Q}_{VC}}{{Q}_{PC}} [ - ( 1 - \frac{{Q}_{PC}}{{Q}_{VC}} ) ] \qquad ( 4 )$$

where [symbol] is the estimated SOC of the first battery cell 28, Q_{VC} is a capacity of the second battery cell, Q_{PC} is capacity of the first battery cell 28, and [symbol] is the estimated SOC of the second battery cell.

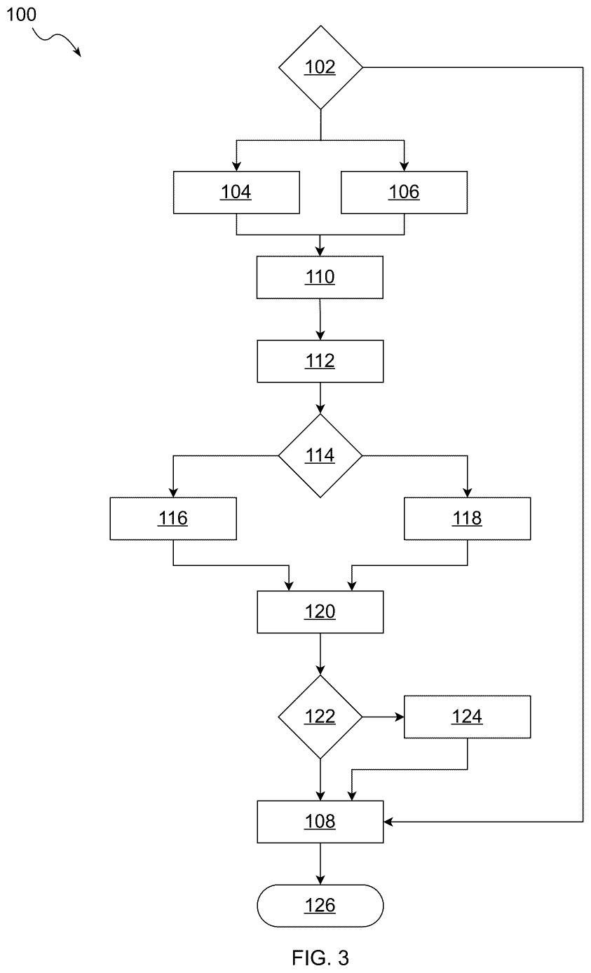

Referring to FIG. 3, a flowchart of the method 100 for determining a state of charge (SOC) of a battery is provided. With reference to FIG. 3 and continued reference to FIG. 2, the method 100 begins at block 102.

At block 102, the controller 14 determines an initial estimated SOC of the first battery cell 28 using OCV-SOC mapping or coulomb counting. The initial estimated SOC may be inaccurate due to accumulated SOC error and/or if the OCV-SOC curve of the first battery cell 28 is relatively flat. If the initial estimated SOC of the first battery cell 28 is within a predetermined SOC range (e.g., greater than 67% and less than 92%), the method 100 proceeds to blocks 104 and 106. If the initial estimated SOC of the first battery cell 28 is not within the predetermined SOC range, the method 100 proceeds to block 108, as will be discussed in greater detail below.

At block 104, the controller 14 determines the measured physical battery current (I) flowing through the battery 16. In an exemplary embodiment, the controller 14 uses the battery management system 18 to determine the measured physical battery current. In a non-limiting example, the controller uses the one or more battery sensors of the battery management system 18 (e.g., a current sensor) to measure the measured physical battery current flowing through the battery 16. After block 104, the method 100 proceeds to block 110, as will be discussed in greater detail below.

At block 106, the controller 14 determines the estimated physical battery current ( [symbol] ). In an exemplary embodiment, the controller 14 determines the estimated physical battery current ( [symbol] ) using the physical battery cell model 30 and Equation 1 as discussed above. After block 106, the method 100 proceeds to block 110.

At block 110, the controller 14 determines a parameter deviation factor (α) of the physical battery cell model 30. In the scope of the present disclosure, the parameter deviation factor (α) describes deviations due to non-idealities of the first battery cell 28. In an exemplary embodiment, the parameter deviation factor (α) is determined by:

$$α = \frac{1}{1 - \frac{{( \overline{I} - )}_{max}}{\overline{I}}} \qquad ( 5 )$$

where α is the parameter deviation factor, Ī is the measured physical battery current, and [symbol] is the estimated physical battery current. After block 110, the method 100 proceeds to block 112.

At block 112, the controller 14 determines a hysteresis deviation constant (d) of the physical battery cell model 30. In the scope of the present disclosure, the hysteresis deviation constant (d) describes deviations due to voltage hysteresis of the first battery cell 28. In an exemplary embodiment, the hysteresis deviation constant (d) is determined by:

$$d = \frac{\vert p \cdot {Q}_{c} \vert}{\vert p \cdot {Q}_{c} \vert + \vert q \cdot {Q}_{d} \vert} {G}_{m} \qquad ( 6 )$$

where d is the hysteresis deviation constant, p is a first calibratable constant, q is a second calibratable constant, Q_{c} is a charge capacity of the first battery cell 28, Q_{d} is a discharge capacity of the first battery cell 28, and Gₘ is a mean difference between a charging open circuit voltage of the first battery cell 28 and a discharging open circuit voltage of the first battery cell 28 within the predetermined SOC range (e.g., between 67% and 92%). After block 112, the method 100 proceeds to block 114.

At block 114, the controller determines a difference between the simulated terminal voltage of the second battery cell ( [symbol] ) and the estimated terminal voltage of the second battery cell ( [symbol] ). The simulated terminal voltage of the second battery cell ( [symbol] ) is determined using the second virtual battery cell model instance 32b and Equation 3. The estimated terminal voltage of the second battery cell ( [symbol] ) is determined using the first virtual battery cell model instance 32a and Equation 2. The controller 14 compares the difference between the simulated terminal voltage of the second battery cell ( [symbol] ) and the estimated terminal voltage of the second battery cell ( [symbol] ) to a predetermined convergence threshold (e.g., 0.05 volts).

If the difference between the simulated terminal voltage of the second battery cell ( [symbol] ) and the estimated terminal voltage of the second battery cell ( [symbol] ) is greater than or equal to the predetermined convergence threshold for at least a predetermined time (e.g., 900 seconds), the method 100 proceeds to block 116, as will be discussed in greater detail below. If the difference between the simulated terminal voltage of the second battery cell ( [symbol] ) and the estimated terminal voltage of the second battery cell ( [symbol] ) is less than the predetermined convergence threshold for at least the predetermined time (e.g., 900 seconds), the method 100 proceeds to block 118, as will be discussed in greater detail below.

At block 116, the controller 14 sets a virtual RC pair resistance (R_{1,VC}) of the second battery cell to a first resistance value in response to determining that the difference between the simulated terminal voltage of the second battery cell ( [symbol] ) and the estimated terminal voltage of the second battery cell ( [symbol] ) is greater than or equal to the predetermined convergence threshold for at least the predetermined time. After block 116, the method 100 proceeds to block 120, as will be discussed in greater detail below.

At block 118, the controller 14 sets the virtual RC pair resistance (R_{1,VC}) of the second battery cell to a second resistance value in response to determining that the difference between the simulated terminal voltage of the second battery cell ( [symbol] ) and the estimated terminal voltage of the second battery cell ( [symbol] ) is less than the predetermined convergence threshold for at least the predetermined time. In a non-limiting example, the second resistance value is less than the first resistance value. After block 118, the method 100 proceeds to block 120.

At block 120, the controller 14 calculates an innovation factor. In an exemplary embodiment, the innovation factor is determined based on the one or more battery parameters, including, for example, the virtual RC pair resistance (R_{1,VC}) of the second battery cell as determined at block 116 or block 118:

$$e = \frac{{R}_{1 , VC}}{{R}_{1 , VC} * {C}_{1 , VC} * s + 1} * ( \overline{I} - ) \qquad ( 7 )$$

where e is the innovation factor, R_{1,VC} is the virtual RC pair resistance, Ī is the measured physical battery current, [symbol] is the estimated physical battery current, C_{1,VC} is a virtual RC pair capacitance, and s is the Laplace variable.

In another exemplary embodiment, the innovation factor is determined based on the one or more battery parameters, including, for example, the virtual RC pair resistance (R_{1,VC}), the parameter deviation factor (α), and the hysteresis deviation constant (d):

$$e = \frac{{R}_{1 , VC}}{{R}_{1 , VC} * {C}_{1 , VC} * s + 1} * [ ( \overline{I} - ) - \frac{α - 1}{α} * \overline{I} + \frac{0.5 * {G}_{m} - d}{α * {R}_{0 , PC}} ] \qquad ( 8 )$$

where e is the innovation factor, R_{1,VC} is the virtual RC pair resistance, C_{1,VC} is a virtual RC pair capacitance, s is the Laplace variable, Ī is the measured physical battery current, [symbol] is the estimated physical battery current, α is the parameter deviation factor, Gₘ is a mean difference between the charging open circuit voltage of the first battery cell and the discharging open circuit voltage of the first battery cell 28 within the predetermined SOC range, d is the hysteresis deviation constant, and R_{0,PC} is a series resistance of the physical battery cell model 30. After block 120, the method 100 proceeds to block 122.

At block 122, the controller 14 determines the estimated SOC of the second battery cell ( [symbol] ) using the Kalman filtering module. In an exemplary embodiment, to determine the estimated SOC of the second battery cell ( [symbol] ), the controller 14 first multiplies the innovation factor determined at block 120 by a Kalman gain factor (K_{g}). In a non-limiting example, the Kalman gain factor is determined based at least in part on the SOC-OCV slope and covariance of the second battery cell. The controller 14 then adds the product of the innovation factor and the Kalman gain factor to a previously estimated SOC of the second battery cell (SOC_{VC,prev.}) to determine the estimated SOC of the second battery cell ( [symbol] ). In a non-limiting example, the previously estimated SOC of the second battery cell is an estimated SOC of the second battery cell determined upon a previous execution of the method 100.

The controller 14 then uses the SOC conversion module 36 to determine the estimated SOC of the first battery cell 28 ( [symbol] ), as discussed above. If the estimated SOC of the first battery cell 28 ( [symbol] ) is within a predetermined SOC range (e.g., greater than 67% and less than 92%), the method 100 proceeds to block 124. If the estimated SOC of the first battery cell 28 ( [symbol] ) is not within the predetermined SOC range, the method 100 proceeds to block 108, as will be discussed in greater detail below.

At block 124, the controller 14 determines the SOC of the battery 16 to be equal to the estimated SOC of the first battery cell 28 ( [symbol] ) determined at block 122. In other words, the controller 14 recalibrates a known baseline SOC of a coulomb counting estimation method for the SOC of the battery 16 by setting the SOC of the battery to be equal to the estimated SOC of the first battery cell 28 ( [symbol] ). After block 124, the method 100 proceeds to block 108.

At block 108, the controller 14 uses coulomb counting to determine the SOC of the battery 16. In the scope of the present disclosure, coulomb counting is a method for estimating battery SOC by tracking an amount of charge flowing into and out of the battery 16 and calculating a change in SOC based on a known baseline SOC. Due to error which accumulates over time, it is advantageous to periodically recalibrate the known baseline SOC as discussed above in reference to block 124. Therefore, at block 108, the controller 14 uses the battery management system 18 to continuously measure the current flowing into/out of the battery 16 and estimates the SOC of the battery 16 based on the known baseline SOC. After block 108, the method 100 proceeds to enter a standby state at block 126.

In an exemplary embodiment, the controller 14 repeatedly exits the standby state 126 and restarts the method 100 at block 102. In a non-limiting example, the controller 14 exits the standby state 126 and restarts the method 100 on a timer, for example, every three hundred milliseconds.

The system 10 and method 100 of the present disclosure offer several advantages. Using the system 10 and method 100 of the present disclosure, the SOC of the battery 16 containing the first battery cell 28 may be estimated using software-based simulation of the second battery cell by taking advantage of the OCV-SOC relationship of the second battery cell. Furthermore, by adjusting the one or more battery parameters of the physical battery cell model 30 and the virtual battery cell model 32, a convergence time of the Kalman filtering module 34 may be decreased.

The description of the present disclosure is merely exemplary in nature and variations that do not depart from the gist of the present disclosure are intended to be within the scope of the present disclosure. Such variations are not to be regarded as a departure from the spirit and scope of the present disclosure.

What is claimed is:

1. A method for determining a state of charge (SOC) of a battery, the method comprising:
determining a measured physical battery current flowing through the battery;
determining an estimated physical battery current using a physical battery cell model, wherein the physical battery cell model is an equivalent circuit model of a first battery cell;
determining an estimated SOC of the battery based at least in part on the measured physical battery current and the estimated physical battery current using a virtual battery cell model, wherein the virtual battery cell model is an equivalent circuit model of a second battery cell, and wherein the second battery cell is a computer-simulated electrochemical battery cell modeled in series with the physical battery cell model; and
determining the SOC of the battery based at least in part on the estimated SOC of the battery.

2. The method of claim 1, wherein determining the estimated physical battery current further comprises:
computing the estimated physical battery current based at least in part on one or more battery parameters of the physical battery cell model, wherein the first battery cell is a lithium-iron phosphate (LiFePO4) battery cell.

3. The method of claim 1, wherein determining the estimated SOC of the battery further comprises:
calculating an innovation factor based at least in part on the measured physical battery current, the estimated physical battery current, and one or more battery parameters of the physical battery cell model; and
determining the estimated SOC of the battery based at least in part on the innovation factor.

4. The method of claim 3, wherein determining the estimated SOC of the battery further comprises:
determining an estimated SOC of the second battery cell using Kalman filtering based at least in part on the innovation factor; and
determining the estimated SOC of the battery based at least in part on the estimated SOC of the second battery cell.

5. The method of claim 3, wherein calculating the innovation factor further comprises:
determining the one or more battery parameters, wherein the one or more battery parameters includes a virtual RC pair resistance of the virtual battery cell model; and
calculating the innovation factor using a formula:
$$e = \frac{{R}_{1 , VC}}{{R}_{1 , VC} * {C}_{1 , VC} * s + 1} * ( \overline{I} - )$$
wherein e is the innovation factor, R_{1,VC} is the virtual RC pair resistance, Ī is the measured physical battery current, [symbol] is the estimated physical battery current, C_{1,VC} is a virtual RC pair capacitance, and s is the Laplace variable.

6. The method of claim 5, wherein determining the one or more battery parameters further comprises:
determining a difference between a simulated virtual battery cell terminal voltage and an estimated virtual battery cell terminal voltage, wherein the simulated virtual battery cell terminal voltage is determined using the virtual battery cell model based on the measured physical battery current, and wherein the estimated virtual battery cell terminal voltage is determined using the virtual battery cell model based on the estimated physical battery current;
setting the virtual RC pair resistance to be equal to a first resistance value in response to determining that the difference between a simulated virtual battery cell terminal voltage and an estimated virtual battery cell terminal voltage is greater than or equal to a predetermined convergence threshold; and
setting the virtual RC pair resistance to be equal to a second resistance value in response to determining that the difference between a simulated virtual battery cell terminal voltage and an estimated virtual battery cell terminal voltage is less than the predetermined convergence threshold, wherein the second resistance value is less than the first resistance value.

7. The method of claim 3, wherein calculating the innovation factor further comprises:
determining the one or more battery parameters, wherein the one or more battery parameters includes a virtual RC pair resistance of the virtual battery cell model;
determining the one or more battery parameters, wherein the one or more battery parameters further includes a parameter deviation factor of the physical battery cell model;
determining the one or more battery parameters, wherein the one or more battery parameters further includes a hysteresis deviation constant of the physical battery cell model;
determining a mean difference between a charging open circuit voltage of the first battery cell and a discharging open circuit voltage of the first battery cell within a predetermined SOC range; and
calculating the innovation factor using a formula:
$$e = \frac{{R}_{1 , VC}}{{R}_{1 , VC} * {C}_{1 , VC} * s + 1} * [ ( \overline{I} - ) - \frac{α - 1}{α} * \overline{I} + \frac{0.5 * {G}_{m} - d}{α * {R}_{0 , PC}} ]$$
wherein e is the innovation factor, R_{1,VC} is the virtual RC pair resistance, C_{1,VC} is a virtual RC pair capacitance, s is the Laplace variable, Ī is the measured physical battery current, [symbol] is the estimated physical battery current, α is the parameter deviation factor, Gₘ is the mean difference between the charging open circuit voltage of the first battery cell and the discharging open circuit voltage of the first battery cell within the predetermined SOC range, d is the hysteresis deviation constant, and R_{0,PC} is a series resistance of the physical battery cell model.

8. The method of claim 7, wherein determining the parameter deviation factor comprises:
determining the parameter deviation factor using a formula:
$$α = \frac{1}{1 - \frac{{( \overline{I} - )}_{max}}{\overline{I}}}$$
wherein α is the parameter deviation factor, Ī is the measured physical battery current, and [symbol] is the estimated physical battery current.

9. The method of claim 7, wherein determining the hysteresis deviation constant further comprises:
determining the hysteresis deviation constant using a formula:
$$d = \frac{\vert p \cdot {Q}_{c} \vert}{\vert p \cdot {Q}_{c} \vert + \vert q \cdot {Q}_{d} \vert} {G}_{m}$$
wherein d is the hysteresis deviation constant, p is a first calibratable constant, q is a second calibratable constant, Q_{c} is a charge capacity of the first battery cell, Q_{d} is a discharge capacity of the first battery cell, and Gₘ is the mean difference between the charging open circuit voltage of the first battery cell and the discharging open circuit voltage of the first battery cell within the predetermined SOC range.

10. The method of claim 1, wherein determining the SOC of the battery further comprises:
comparing an estimated SOC of the battery to a predetermined SOC range;
determining the SOC of the battery to be equal to the estimated SOC of the battery in response to determining that the estimated SOC of the battery is within the predetermined SOC range; and
determining the SOC of the battery using coulomb counting in response to determining that the estimated SOC of the battery is outside of the predetermined SOC range.

11. A system for determining a state of charge (SOC) of a battery for a vehicle, the system comprising:
the battery including a first battery cell;
one or more battery sensors in electrical communication with the battery; and
a controller in electrical communication with the one or more battery sensors, wherein the controller is programmed to:
determine a measured physical battery current flowing through the battery using the one or more battery sensors;
determine an estimated physical battery current using a physical battery cell model, wherein the physical battery cell model is an equivalent circuit model of the first battery cell; and
determine the SOC of the battery based at least in part on the measured physical battery current and the estimated physical battery current using a virtual battery cell model, wherein the virtual battery cell model is an equivalent circuit model of a second battery cell, and wherein the second battery cell is a computer-simulated electrochemical battery cell modeled in series with the physical battery cell model.

12. The system of claim 11, wherein to determine the SOC of the battery, the controller is further programmed to:
calculate an innovation factor based at least in part on the measured physical battery current, the estimated physical battery current, and one or more battery parameters of the physical battery cell model;
determine an estimated SOC of the second battery cell using Kalman filtering based at least in part on the innovation factor; and
determine the SOC of the battery based at least in part on the estimated SOC of the second battery cell.

13. The system of claim 12, wherein to calculate the innovation factor, the controller is further programmed to:
determine the one or more battery parameters, wherein the one or more battery parameters includes a virtual RC pair resistance of the virtual battery cell model; and
calculate the innovation factor using a formula:
$$e = \frac{{R}_{1 , VC}}{{R}_{1 , VC} * {C}_{1 , VC} * s + 1} * ( \overline{I} - )$$
wherein e is the innovation factor, R_{1,VC} is the virtual RC pair resistance, Ī is the measured physical battery current, [symbol] is the estimated physical battery current, C_{1,VC} is a virtual RC pair capacitance, and s is the Laplace variable.

14. The system of claim 13, wherein to determine the one or more battery parameters, the controller is further programmed to:
determine a difference between a simulated virtual battery cell terminal voltage and an estimated virtual battery cell terminal voltage, wherein the simulated virtual battery cell terminal voltage is determined using the virtual battery cell model based on the measured physical battery current, and wherein the estimated virtual battery cell terminal voltage is determined using the virtual battery cell model based on the estimated physical battery current;
set the virtual RC pair resistance to be equal to a first resistance value in response to determining that the difference between a simulated virtual battery cell terminal voltage and an estimated virtual battery cell terminal voltage is greater than or equal to a predetermined convergence threshold; and
set the virtual RC pair resistance to be equal to a second resistance value in response to determining that the difference between a simulated virtual battery cell terminal voltage and an estimated virtual battery cell terminal voltage is less than the predetermined convergence threshold, wherein the second resistance value is less than the first resistance value.

15. The system of claim 12, wherein to calculate the innovation factor, the controller is further programmed to:
determine the one or more battery parameters, wherein the one or more battery parameters includes a virtual RC pair resistance of the virtual battery cell model;
determine the one or more battery parameters, wherein the one or more battery parameters further includes a parameter deviation factor of the physical battery cell model;
determine the one or more battery parameters, wherein the one or more battery parameters further includes a hysteresis deviation constant of the physical battery cell model;
determine a mean difference between a charging open circuit voltage of the first battery cell and a discharging open circuit voltage of the first battery cell within a predetermined SOC range; and
calculate the innovation factor using a formula:
$$e = \frac{{R}_{1 , VC}}{{R}_{1 , VC} * {C}_{1 , VC} * s + 1} * [ ( \overline{I} - ) - \frac{α - 1}{α} * \overline{I} + \frac{0.5 * {G}_{m} - d}{α * {R}_{0 , PC}} ]$$
wherein e is the innovation factor, R_{1,VC} is the virtual RC pair resistance, C_{1,VC} is a virtual RC pair capacitance, s is the Laplace variable, Ī is the measured physical battery current, [symbol] is the estimated physical battery current, a is the parameter deviation factor, Gₘ is the mean difference between the charging open circuit voltage of the first battery cell and the discharging open circuit voltage of the first battery cell within the predetermined SOC range, d is the hysteresis deviation constant, and R_{0,PC} is a series resistance of the physical battery cell model.

16. The system of claim 15, wherein to determine the parameter deviation factor, the controller is further programmed to:
determine the parameter deviation factor using a formula:
$$α = \frac{1}{1 - \frac{{( \overline{I} - )}_{max}}{\overline{I}}}$$
wherein α is the parameter deviation factor, Ī is the measured physical battery current, and [symbol] is the estimated physical battery current.

17. The system of claim 15, wherein to determine the hysteresis deviation constant, the controller is further programmed to:
determine the hysteresis deviation constant using a formula:
$$d = \frac{\vert p \cdot {Q}_{c} \vert}{\vert p \cdot {Q}_{c} \vert + \vert q \cdot {Q}_{d} \vert} {G}_{m}$$
wherein d is the hysteresis deviation constant, p is a first calibratable constant, q is a second calibratable constant, Q_{c} is a charge capacity of the first battery cell, Q_{d} is a discharge capacity of the first battery cell, and Gₘ is the mean difference between the charging open circuit voltage of the first battery cell and the discharging open circuit voltage of the first battery cell within the predetermined SOC range.

18. A method for determining a state of charge (SOC) of a battery, the method comprising:
determining a measured physical battery current flowing through the battery;
determining an estimated physical battery current using a physical battery cell model, wherein the physical battery cell model is an equivalent circuit model of a first battery cell, wherein the first battery cell is a lithium-iron phosphate (LiFePO4) battery cell; and
determining the SOC of the battery based at least in part on the measured physical battery current and the estimated physical battery current using a virtual battery cell model, wherein the virtual battery cell model is an equivalent circuit model of a second battery cell, wherein the second battery cell is a computer-simulated electrochemical battery cell modeled in series with the physical battery cell model, and wherein the second battery cell is a nickel cobalt manganese (NCM) battery cell.

19. The method of claim 18, wherein determining the SOC of the battery further comprises:
calculating an innovation factor based at least in part on the measured physical battery current, the estimated physical battery current, and one or more battery parameters of the physical battery cell model; and
determining an estimated SOC of the second battery cell using Kalman filtering based at least in part on the innovation factor; and
determining the SOC of the battery based at least in part on the estimated SOC of the second battery cell.

20. The method of claim 19, wherein calculating the innovation factor further comprises:
determining a difference between a simulated virtual battery cell terminal voltage and an estimated virtual battery cell terminal voltage, wherein the simulated virtual battery cell terminal voltage is determined using the virtual battery cell model based on the measured physical battery current, and wherein the estimated virtual battery cell terminal voltage is determined using the virtual battery cell model based on the estimated physical battery current;
setting a virtual RC pair resistance to be equal to a first resistance value in response to determining that the difference between a simulated virtual battery cell terminal voltage and an estimated virtual battery cell terminal voltage is greater than or equal to a predetermined convergence threshold;
setting the virtual RC pair resistance to be equal to a second resistance value in response to determining that the difference between a simulated virtual battery cell terminal voltage and an estimated virtual battery cell terminal voltage is less than the predetermined convergence threshold, wherein the second resistance value is less than the first resistance value; and
calculating the innovation factor using a formula:
$$e = \frac{{R}_{1 , VC}}{{R}_{1 , VC} * {C}_{1 , VC} * s + 1} * ( \overline{I} - )$$
wherein e is the innovation factor, R_{1,VC} is the virtual RC pair resistance, Ī is the measured physical battery current, [symbol] is the estimated physical battery current, C_{1,VC} is a virtual RC pair capacitance, and s is the Laplace variable.
